(19) United States
(12) Patent Application Publication
(10) Pub. No.: US 2008/0132071 A1
(43) Pub. Date: Jun. 5, 2008

(54) Composition and method for enhancing pot life of hydrogen peroxide-containing CMP slurries

(75) Inventors: Wang Yuchun, Naperville, IL (US); Bin Lu, Naperville, IL (US); John Parker, Naperville, IL (US); Roger Martin, Aurora, IL (US)

Correspondence Address: STEVEN WESEMAN;ASSOCIATE GENERAL COUNSEL, I.P., CABOT MICROELECTRONICS CORPORATION, 870 NORTH COMMONS DRIVE, AURORA, IL, 60504, US

(73) Assignee: Cabot Microelectronics Corporation

(21) Appl. No.: 12/011,435

(22) Filed: Jan. 25, 2008

Related U.S. Application Data
(62) Division of application No. 11/238,236, filed on Sep. 29, 2005.

(51) Int. Cl. H01L 21/461

(52) U.S. Cl. 438/692; 257/E21.483

(57) ABSTRACT

A method for providing CMP slurries for copper CMP that have improved pot life by ameliorating hydrogen peroxide degradation in slurries. The method comprises a composition that has a transition metal content of less than about 5 parts per million (ppm), preferably less than about 2 ppm. Preferably the method comprises a composition containing less than about 2 ppm of yttrium, zirconium, and/or iron.

### CROSS-REFERENCE TO RELATED PATENT APPLICATIONS

This patent application is a divisional of copending U.S. patent application Ser. No. 11/238,236, filed Sep. 29, 2005.

### FIELD OF THE INVENTION

This invention relates to compositions and methods for chemical-mechanical polishing (CMP). More particularly, this invention relates to chemical-mechanical polishing compositions containing relatively low levels of transition metal materials, and to methods of utilizing the CMP composition with hydrogen peroxide to provide oxidative CMP slurries with improved pot life stability.

### BACKGROUND OF THE INVENTION

Compositions and methods for planarizing or polishing the surface of a substrate (e.g., a semiconductor wafer) are well known in the art. Polishing compositions (also known as polishing slurries) typically contain an abrasive material in an aqueous solution and are applied to a surface by contacting the surface with a polishing pad saturated with the slurry composition. In addition, such slurries also commonly utilize chemical additives that enhance removal of materials from the surface of the substrate via chemical reactions with the surface. Such chemically-enhanced polishing is commonly referred to as chemical-mechanical polishing (CMP). Frequently, oxidizing agents, such as hydrogen peroxide, are used in CMP slurries to oxidize the substrate surface during polishing, which aids in material removal. For example, hydrogen peroxide frequently is utilized in CMP of copper-containing semiconductor wafers.

Common abrasive materials used in CMP slurries in combination with hydrogen peroxide (e.g., for copper CMP applications) include silicon dioxide (silica) and aluminum oxide (alumina)-based abrasives. Because of the relative chemical instability of hydrogen peroxide-containing CMP slurries, due at least in part to transition metal contaminants generated during preparation of the abrasive medium and/or generated during the planarization process, such CMP slurries have a limited usable lifetime (commonly referred to a pot life stability). The limited pot life stability of hydrogen peroxide-containing CMP slurries contributes to the costs of semiconductor wafer manufacture, due to the need to frequently replenish the amount hydrogen peroxide in the slurry.

Accordingly, there is an ongoing need for silica- and alumina-containing CMP slurries with improved pot life stability when used in combination with hydrogen peroxide, particularly for use in copper CMP. There is also an ongoing need for methods of enhancing the pot life of hydrogen peroxide-containing CMP slurries. The present invention provides such improved CMP compositions and methods. These and other advantages of the invention will be apparent from the description of the invention provided herein.

### BRIEF SUMMARY OF THE INVENTION

The invention provides a composition suitable for copper CMP in the presence of hydrogen peroxide. The composition comprises an abrasive powder, such as a silica and/or alumina abrasive, and a liquid carrier for the abrasive. The composition has a transition metal content of less than about 5 parts per million (ppm), preferably less than about 2 ppm, prior to use in wafer planarization. More preferably, the CMP slurry is, at least initially, substantially free from transition metal contaminants. While contamination with some transition metals during planarization is unavoidable (i.e., because transition metals are being abraded from the wafer surface), providing a relatively low transition metal content in the slurry prior to initiating wafer planarization surprisingly enhances the pot life of the hydrogen peroxide containing CMP slurries by a significant factor, i.e., up to about 100% increase in useable pot life.

The present invention also provides a method for enhancing the pot life of a copper CMP slurry containing hydrogen peroxide. The method comprises maintaining a transition metal content in the slurry, prior to initiation of planarization, at a value of less than about 5 ppm, preferably less than about 2 ppm. In one embodiment, the method further comprises maintaining the pH of the slurry during planarization at a value of about 7 or less (i.e., at a neutral or acidic pH). The methods of the invention provide for stable, reproducible copper removal rates over longer periods of time than conventional CMP slurries.

### DETAILED DESCRIPTION OF THE INVENTION

The present invention is directed to compositions useful in combination with hydrogen peroxide in CMP applications, such as copper CMP. The CMP compositions of the present invention, when combined with hydrogen peroxide, ameliorate the decomposition of hydrogen peroxide, affording a significantly improved pot life relative to conventional CMP slurries. The CMP compositions of the invention comprise an abrasive powder in a liquid carrier. The compositions have a transition metal content of less than about 5 parts per million (ppm), preferably less than about 2 ppm, prior to use in CMP of a semiconductor wafer. Preferably, the abrasive powder is a silica abrasive, an alumina abrasive, or a combination thereof. Most preferably, the CMP slurries of the invention are substantially free from transition metal contaminants prior to use in a wafer planarization process. The transition metals (e.g., metals of Groups 3-12 of the Periodic Table, as defined by the International Union of Pure and Applied Chemistry (IUPAC), 1993) that may be present in a CMP slurry of the invention can be in any chemical form (e.g., as soluble metal ions, insoluble metal oxides, soluble or insoluble metal salts, metal complexes, and the like); however, the transition metal content of the CMP slurry is specified in parts per million on a transition metal elemental weight basis, i.e., on the basis of elemental transition metals, regardless of the actual form of the transition metal materials that may be present in the slurry.

As used herein, all references to Groups from the Periodic Table refer to the 1993 IUPAC periodic table, described above, and incorporated herein by reference, which numbers the transition metal Groups as 3-12 (Group 3 being the scandium group and Group 12 being the zinc group).

The abrasive can be any abrasive powder suitable for CMP applications with hydrogen peroxide. Preferably, the abrasive is a silica- or alumina-based abrasive, many of which are well known in the art. For example, the abrasive can be α-alumina, fumed alumina, fumed silica, and the like. In some embodiments, the abrasive preferably comprises α-alumina having a mean particle size of about 100 nm or greater (e.g., about 200 nm or greater, or about 250 nm or greater). Typically, the (α-alumina is used in combination with a softer abrasive (e.g., fumed alumina). The abrasive can have any suitable particle size. In some embodiments, the use of α-alumina having a mean particle size of about 100 nm or greater (e.g., about 200 nm or greater, or about 250 nm or greater) is preferred. Other non-transition metal-based abrasives can be utilized in combination with the silica and alumina abrasives as well, such as silicon nitride, silicon carbide, and the like. The mean particle size is reported as determined by light scattering, for example, using a Hariba LA-910 instrument.

Any suitable amount of abrasive can be present in the CMP composition. Typically, about 0.01 percent by weight (wt. %) or more (e.g., about 0.03 wt. % or more, or about 0.05 wt. % or more) abrasive will be present in the polishing composition. More typically, about 0.1 wt. % or more abrasive will be present in the polishing composition. The amount of abrasive in the polishing composition typically will not exceed about 50 wt. %, more typically will not exceed about 20 wt. %. Preferably, the amount of abrasive in the polishing composition is about 0.5 wt. % to about 10 wt. %. In some embodiments, the amount of abrasive in the polishing composition desirably is about 0.1 wt. % to about 5 wt. %.

In one preferred embodiment the slurry comprises about 0.4 to about 0.7 percent by weight of (α-alumina in deionized water as the liquid carrier. The CMP composition of this preferred embodiment has a total content of transition metal from Groups 3, 4, and 8 of the Periodic Table (e.g., yttrium, zirconium, and iron) of less than about 2 ppm (i.e., on an elemental transition metal basis) prior to initiating planarization. Preferably, each of the foregoing individual transition metals is present in the composition in an amount less than about 1 ppm, provided the total transition metal content is less than about 5 ppm.

In a particularly preferred embodiment, the composition comprises less than about 1 ppm of Group 4 transition metals (e.g., titanium and zirconium). It is preferred that the CMP slurry is substantially free from Group 4 transition metals. In some preferred embodiments, the CMP composition comprises less than about 1 ppm of zirconium, more preferably less than about 0.1 ppm of zirconium. Most preferably, the CMP composition is substantially free of zirconium contaminants. In other preferred embodiments, the CMP composition comprises less than about 1 ppm of yttrium, more preferably less than about 0.1 ppm of yttrium. Most preferably, the CMP composition is substantially free from yttrium contaminants.

In yet another preferred embodiment, the CMP composition comprises less than about 1 ppm of Group 8 transition metals (e.g., iron). Iron contamination can arise from exposure of the CMP composition to certain iron-containing equipment during manufacture or storage, particularly when the slurry is acidic and after combining the slurry with hydrogen peroxide. Preferably, the iron content of the slurry is less than about 1 ppm, more preferably, less than about 0.2 ppm. Most preferably, the CMP slurry is substantially free from iron contaminants.

Preferably, the CMP compositions of the invention have a neutral or acidic pH, e.g., about 7 or less, more preferably in the range of about 5 to about 7. Maintaining the pH of the hydrogen peroxide-containing slurry in the neutral to acidic range results in a reduced degree of hydrogen peroxide degradation over time, relative to slurries having basic pH.

A liquid carrier is used to facilitate the application of the abrasive and any optional additives to the surface of a suitable substrate to be polished or planarized. The liquid carrier is typically an aqueous carrier and can be water alone, can comprise water and a suitable water-miscible solvent, or can be an emulsion. Suitable water-miscible solvents include alcohols such as methanol, ethanol, and the like. Preferably, the aqueous carrier consists of water, more preferably deionized water.

The CMP compositions of the invention can additionally include one or more polishing additives. Non-limiting examples of polishing additives include surfactants, viscosity modifying agents, buffers, acids, bases, oxidizing agents, salts, chelating agents, and the like.

The CMP compositions can comprise any suitable amount of polishing additive(s). In some embodiments, the CMP composition comprises about 0.0001 wt. % or more of such polishing additive(s), e.g., about 0.001 wt. % to about 5 wt. % of such polishing additive(s).

Examples of suitable oxidizing agents for use in the CMP compositions of the invention include, without limitation, peroxy-type oxidizers, per-type oxidizers, organic oxidizers, and the like. The CMP systems can contain any suitable amount of an oxidizing agent. The CMP system preferably comprises about 0.1 to about 20 wt. % oxidizing agent.

The per-type oxidizer, if present, can be any suitable per-type oxidizer. Suitable per-type oxidizers include inorganic and organic per-compounds. A per-compound (as defined by Hawley's Condensed Chemical Dictionary) is a compound containing at least one peroxy group (—O—O—) or a compound containing an element in its highest oxidation state. Examples of compounds containing at least one peroxy group include but are not limited to hydrogen peroxide and its adducts such as urea hydrogen peroxide and percarbonates, organic peroxides such as benzoyl peroxide, peracetic acid, and di-tert-butyl peroxide, monopersulfates (SO₅²⁻), dipersulfates (S₂O₈²⁻), and sodium peroxide. Examples of compounds containing an element in its highest oxidation state include but are not limited to periodic acid, periodate salts, perbromic acid, perbromate salts, perchloric acid, perchlorate salts, perboric acid, perborate salts, and permanganates. The per-type oxidizer preferably is selected from the group consisting of hydrogen peroxide, persulfate salts (e.g., ammonium persulfate), periodate salts, and permanganate salts. More preferably, the per-type oxidizer is ammonium persulfate or hydrogen peroxide.

The peroxy-type oxidizer is a compound containing at least one peroxy group and is selected from the group consisting of organic peroxides, inorganic peroxides, and mixtures thereof. Examples of compounds containing at least one peroxy group include but are not limited to hydrogen peroxide and its adducts such as urea hydrogen peroxide and percarbonates, organic peroxides such as benzoyl peroxide, peracetic acid, and di-tert-butyl peroxide, monopersulfates (SO₅²⁻), dipersulfates (S₂O₈²⁻), and sodium peroxide. Preferably, the peroxy-type oxidizer is hydrogen peroxide.

Examples of suitable organic oxidizers include organic ring-containing compounds having an unsaturated hydrocarbon ring, an unsaturated heterocyclic ring, or a combination thereof, and preferably having at least one O-, N-, and/or S-containing substituent on the ring. Non-limiting examples of suitable organic oxidizers include, a compound having at least one quinone moiety (e.g., an anthraquinone, a naphthoquinone, a benzoquinone, and the like), a nicotinamide compound, a paraphenylenediamine compound, a phenazine compound, a thionine compound, a phenoxazine compound, phenoxathiin compound, an indigo compound, an indophenol compound, a viologen compound, or any combination thereof.

Preferably, the CMP compositions of the invention include or are utilized in combination with hydrogen peroxide. The hydrogen peroxide is utilized in an amount in the range of about 0.1 to about 3 percent by weight, more preferably about 0.5 to about 1.5 percent by weight. In a particularly preferred embodiment, the CMP composition is kept free from hydrogen peroxide until just prior to utilizing the slurry for copper removal in a CMP process. A peroxide-free CMP composition is mixed with hydrogen peroxide to form a peroxide-containing slurry, which is then fed to a copper-containing a semiconductor wafer in a CMP apparatus. The CMP apparatus typically includes a rotating, carrousel-like platen, in which the wafers are mounted, and a rotating polishing pad, which contacts the copper-containing surface of the wafers. The hydrogen peroxide-containing CMP composition is fed to the surface of the wafers that is in contact with the polishing pad, to facilitate removal of copper and other materials from the wafer surface.

A method for enhancing the pot life of a hydrogen peroxide-containing slurry used in semiconductor wafer planarization. The method comprises maintaining a transition metal content in the slurry at a value of less than about 5 part per million (ppm) prior to initiation of chemical-mechanical polishing of a semiconductor wafer. Preferably the transition metal content of the slurry is maintained at less than about 2 ppm prior to initiation of wafer planarization. Optionally, additional hydrogen peroxide can be added to the slurry storage tank to partially compensate for hydrogen peroxide that has degraded during storage.

In a preferred method embodiment, the content of any individual transition metal from Groups 3, 4, and 6-12 of the Periodic Table (e.g., zirconium, zinc, titanium, nickel, manganese, iron, copper, chromium, cobalt, and yttrium) is maintained at less than about 1 ppm prior to initiation of CMP, provided the total transition metal content is maintained at less than about 5 ppm prior to initiation of wafer planarization. More preferably, the total content of Group 3, 4, and 6-12 transition metals in the slurry is maintained at an amount of less than about 2 ppm prior to initiation of wafer planarization. It is preferred that the content of Group 3 (e.g., yttrium) and/or Group 4 (e.g., zirconium) transition metals be kept at an amount of less than about 0.1 ppm, prior to initiating planarization.

Such transition metal levels can be maintained in the slurry by minimizing contact of the slurry with transition metal materials during manufacturing of the slurry and slurry components or during storage of the slurry (i.e., prior to initiation of planarization). For example, the silica and or alumina abrasive in the CMP composition preferably is manufactured using non-transition metal grinding media (e.g., using an alumina grinding medium rather than a zirconia grinding medium). In addition, the slurries can be stored in plastic containers or plastic lined containers, rather than steel containers, and the like.

Iron contamination can arise even after manufacture of the CMP composition, for example, by exposure of the slurry to iron-containing equipment, storage hoppers, and the like. In some preferred method embodiments, the iron content of the slurry is maintained at an amount of less than about 1 ppm, preferably less than about 0.2 ppm prior to initiating wafer planarization.

Preferably, the pH of the hydrogen peroxide-containing slurry is maintained at a neutral or acidic value, e.g., in the range of about 5 to about 7 prior to planarization. Maintaining a relatively neutral pH during the planarization process can help to minimize iron contamination from the CMP apparatus used in the process, as well.

The following examples further illustrate the invention but, of course, should not be construed as in any way limiting its scope.

### EXAMPLE 1

This example demonstrates the effect of transition metal content of a hydrogen peroxide-containing CMP slurry on pot life.

A polishing composition of the invention (A-1) was prepared by milling α-alumina in deionized water with an α-alumina-based grinding medium. The resulting CMP composition, A-1, had an α-alumina content of about 0.5 percent by weight. A conventional CMP composition (C-1) was prepared by grinding a slurry of α-alumina in deionized water using a zirconium dioxide grinding medium. Composition C-1 had an α-alumina content of about 0.5 percent by weight. The transition metal content of each slurry (A-1 and C-1), as well as the levels of selected non-transition metal elements were determined by inductively coupled plasma spectrometry (ICP), and are shown in Table 1. Both slurries had pH values in the range of about 6 to about 9.

Each slurry (A-1 and C-1) was separately combined with about 1 percent by weight of hydrogen peroxide, and the pot life of the slurry was determined by monitoring the copper removal rate obtained with each slurry under a standard copper CMP polishing condition (1.5 psi down force, platen rotation speed of 53 rpm, polishing pad rotation speed of 67 rpm, 300 mL per minute slurry flow rate, on a REFLEXION® Model CMP apparatus (Applied Materials, Inc, Santa Clara, Calif.) using a standard polyurethane polishing pad) over a period of about 72 hours. Increasing copper removal rates indicate slurry degradation (e.g., hydrogen peroxide degradation). A target removal rate is less than about 3500 Å/min (e.g., around 3000 Å/min). Higher removal rates result in unacceptable planarization defects in the polished wafers, such as dishing and erosion. Composition A-1 (of the invention) maintained a copper removal rate of less than about 3300 Å/min over the entire 72 hour evaluation period, whereas conventional slurry C-1 exhibited a removal rate that drifted up to about 5000 Å/min over 72 hours. These results demonstrate the effectiveness of the CMP compositions of the invention for enhancing pot life of hydrogen peroxide containing CMP slurries.

TABLE 1
Elemental analyses for CMP compositions

| | Composition C-1 | Composition A-1 |
|---|---|---|
| Element | Element Conc. (ppm) | Element Conc. (ppm) |
| Ca | 0.18 | 0.32 |
| Co | <0.025 | <0.025 |
| Cr | 0.034 | 0.033 |
| Cu | <0.025 | <0.025 |
| Fe | 0.57 | 0.67 |
| K | 67 | 68 |
| Mg | 10 | 12 |
| Mn | 0.076 | 0.084 |
| Na | 3.3 | 0.44 |
| Ni | <0.025 | <0.025 |
| Ti | 0.14 | 0.18 |
| Zn | 0.21 | 0.25 |
| Zr | 90 | 0.068 |

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A method for enhancing the pot life of a chemical-mechanical polishing (CMP) slurry during semiconductor wafer planarization, which comprises maintaining the amount of transition metals in the slurry at a value of less than about 5 part per million (ppm) prior to initiating planarization.

2. The method of claim 1 wherein the transition metal content is maintained at less that about 2 ppm.

3. The method of claim 1 wherein the amount of any transition metal selected from Groups 3, 4, and 8 of the Periodic Table present in the slurry is maintained at less than about 1 ppm.

4. The method of claim 3 wherein the transition metal is selected from the group consisting of yttrium, zirconium, and iron.

5. The method of claim 1 wherein the total amount of transition metals selected from Groups 3, 4, and 8 of the Periodic Table present in the slurry is maintained at less than about 2 ppm.

6. The method of claim 1 wherein the amount of any transition metal from Group 3 and Group 4 of the Periodic Table is maintained at an amount of less than about 1 ppm.

7. The method of claim 1 wherein the amount of zirconium present in the slurry is maintained at a value of less than about 1 ppm.

8. The method of claim 1 wherein the amount of zirconium in the slurry is maintained at an amount of less than about 0.1 ppm.

9. The method of claim 1 wherein the amount of iron in the slurry is maintained at an amount of less than about 1 ppm.

10. The method of claim 1 further comprising maintaining the pH of the slurry at a value of about 7 or less.
